(19) United States
(12) Patent Application Publication
(10) Pub. No.: US 2022/0305586 A1
(43) Pub. Date: Sep. 29, 2022

(54) LASER DEFECT REMOVAL APPARATUS AND WINDOW DEFECT REMOVAL METHOD

(71) Applicant: Samsung Display Co., Ltd., Yongin-Si (KR)

(72) Inventors: CHULJIN YIM, Hwaseong-si (KR); HYORIN LEE, Asan-si (KR); JUNGHYUK HAN, Yongin-si (KR); JEONG SEOK LEE, Suwon-si (KR)

(21) Appl. No.: 17/530,939

(22) Filed: Nov. 19, 2021

(30) Foreign Application Priority Data
Mar. 26, 2021 (KR) 10-2021-0039367

(51) Int. Cl. B23K 26/354; B23K 26/073; B23K 26/03; B23K 26/00; C03C 23/00

(52) U.S. Cl. CPC B23K 26/354; B23K 26/073; B23K 26/032; B23K 26/0006; C03C 23/0025; B23K 26/08

(57) ABSTRACT

A window defect removal method includes inspecting a plurality of windows to select a defective window among the windows, providing a laser beam generator on the defective window, and irradiating a scratch of the defective window with a laser beam to remove the scratch. The laser beam generator generates the laser beam in a wavelength range from about 780 nm to about 100,000 nm.

This application claims priority to Korean Patent Application No. 10-2021-0039367, filed on Mar. 26, 2021, and all the benefits accruing therefrom under 35 U.S.C. § 119, the content of which in its entirety is herein incorporated by reference.

### BACKGROUND

### 1. Field

The invention relates to a laser defect removal apparatus and a window defect removal method using the laser defect removal apparatus.

### 2. Description of the Related Art

A display device may include a display panel that displays images and a window that is disposed on and protects the display panel, which may include a plurality of pixels and a drive part that drives the pixels.

Glass may be included in the window that protects the display panel against external impact and/or scratches.

The window is an element which implements specifications for product appearance and whose quality of outward view holds an important position.

### SUMMARY

In an display device including a display panel and a window, the window possibly suffers from scratches that are continuously generated or induced in all processes including fabrication and transfer, and the occurrence of defects may not be fundamentally prevent, with the result that a rework is desired to remove such defects in the window.

Embodiments of the invention provide a laser defect removal apparatus and a window defect removal method using the laser defect removal apparatus which reduces processing time for a window, difference in quality, occurrence of additional defects, and damage to the window and which improves a surface planarization of the window.

According to an embodiment of the invention, a window defect removal method includes: inspecting a plurality of windows to select a defective window of the windows; providing a laser beam generator on the defective window; and irradiating a scratch of the defective window with a laser beam to remove the scratch. In such an embodiment, the laser beam generator generates the laser beam in a wavelength range from about 780 nm to about 100,000 nm.

In an embodiment, the inspecting the windows to select the defective window may include selecting a window in which the scratch exits as the defective window.

In an embodiment, the laser beam generator may move from one lateral surface of the scratch toward another lateral surface of the scratch along an extending direction of the scratch such that the laser beam may be radiated to an entirety of the scratch.

In an embodiment, the irradiating the scratch of the defective window with the laser beam to remove the scratch may include allowing the laser beam to liquefy the scratch and surroundings thereof and then solidifying the liquefied scratch and liquefied surroundings thereof

In an embodiment, a width of the laser beam may be set to be a width of the scratch. In such an embodiment, the width of the scratch may be defined in a direction orthogonal to a traveling direction of the laser beam.

In an embodiment, the laser beam may be a spot type laser beam, a surface type laser beam, or a line type laser beam.

In an embodiment, a radiation time of the laser beam may be equal to or less than about 1 minute.

In an embodiment, the laser beam may have a wavelength of about 10,600 nm.

In an embodiment, the window may include at least one selected from glass, ceramic and ceramic glass.

In an embodiment, the method may further include inspecting to determine whether or not the scratch is visible on a location to which the laser beam is radiated.

In an embodiment, whether or not the scratch is visible may be determined by a naked eye.

In an embodiment, the inspecting the windows to select the defective window may include: allowing an optical tool to capture images of the windows; and allowing a controller to select a defective image among the images of the windows.

In an embodiment, the controller may control a movement of the laser beam generator to provide the laser beam to the defective window corresponding to the defective image, and may control an operation of selecting the defective window and an operation of removing the scratch of the defective window.

According to an embodiment of the invention, a laser defect removal apparatus includes: an optical tool on a window; a laser beam generator which is transferred between the optical tool and the window, in a direction parallel to a plane of the window; and a controller connected to the optical tool and the laser beam generator, where the controller controls an operation of each of the optical tool and the laser beam generator. In such an embodiment, the laser beam generator generates a laser beam in a wavelength range from about 780 nm to about 100,000 nm.

In an embodiment, the laser beam generated from the laser beam generator may be radiated along an extending direction of the scratch from one lateral surface of a scratch of the window toward another lateral surface of the scratch. In such an embodiment, the scratch and surroundings thereof may be liquefied by the laser beam and may then be solidified.

In an embodiment, a width of the laser beam may be set to be a width of the scratch, and the width of the scratch may be defined in a direction orthogonal to a traveling direction of the laser beam. In such an embodiment, the laser beam may be a spot type laser beam, a surface type laser beam, or a line type laser beam.

In an embodiment, a radiation time of the laser beam may be equal to or less than about 1 minute.

### BRIEF DESCRIPTION OF THE DRAWINGS

FIG. 1 illustrates a perspective view showing a laser defect removal apparatus according to an embodiment of the invention.

FIG. 2 illustrates a flow chart showing a window defect removal method according to an embodiment of the invention.

FIGS. 3 to 8B illustrate diagrams showing a window defect removal method according to an embodiment of the invention.

FIG. 9 illustrates a perspective view showing a display device fabricated by using a window according to an embodiment of the invention.

FIG. 10 illustrates a cross-sectional view showing an embodiment of the display device depicted in FIG. 9.

FIG. 11 illustrates a perspective view showing a laser defect removal apparatus according to an alternative embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this description, when a certain component (or region, layer, portion, etc.) is referred to as being “on”, “connected to”, or “coupled to” other component(s), the certain component may be directly disposed on, directly connected to, or directly coupled to the other component(s) or at least one intervening component may be present therebetween. In contrast, when an element is referred to as being “directly on” another element, there are no intervening elements present.

Like numerals indicate like components. Moreover, in the drawings, thicknesses, ratios, and dimensions of components are exaggerated for effectively explaining the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below.

The device may be otherwise oriented (rotated 90 degrees or at other orientations) and the spatially relative descriptors used herein interpreted accordingly.

It The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms used herein including technical and scientific terms have the same meaning generally understood by one of ordinary skilled in the art. Also, terms as defined in dictionaries generally used should be understood as having meaning identical or meaning contextually defined in the art and should not be understood as ideally or excessively formal meaning unless definitely defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

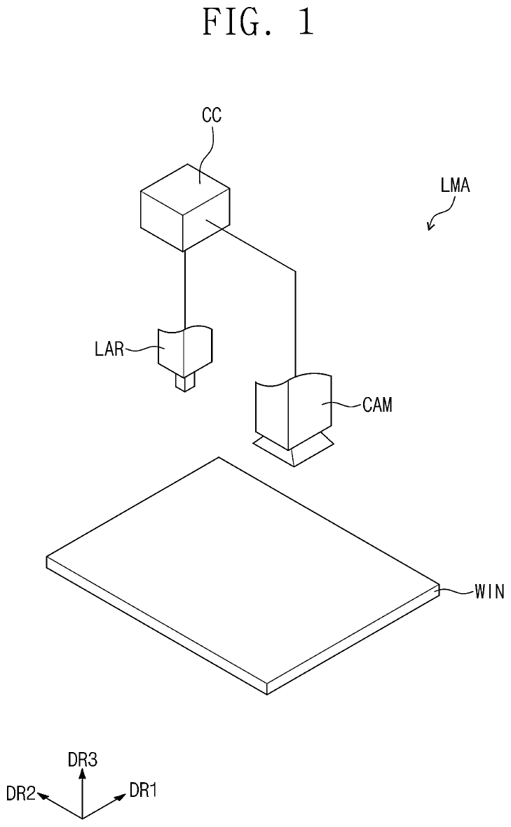

FIG. 1 illustrates a perspective view showing a laser defect removal apparatus according to an embodiment of the invention.

Referring to FIG. 1, an embodiment of a laser defect removal apparatus LMA may include an optical tool CAM, a laser beam generator LAR, and a controller CC. Herein, a laser defect removal apparatus may mean an apparatus that removes defects using a laser.

In such an embodiment, the optical tool CAM may be disposed on window WIN of a processing target.

The controller CC may receive a captured image of the window WIN from the optical tool CAM. The controller CC may inspect an image provided from the optical tool CAM to determine whether scratches are on the window WIN or not.

In one embodiment, for example, the controller CC may be connected through a communication cable to the optical tool CAM, but not being limited thereto or thereby.

In one alternative embodiment, for example, an image may be provided from the optical tool CAM through wireless communication to the controller CC. The controller CC may be a computer that includes a processor and a communication interface for communication with the optical tool CAM.

Depending on the presence of the scratches on the window WIN, the controller CC may control the laser beam generator LAR such that the laser beam generator LAR may be disposed on the window WIN. The controller CC may control the laser beam generator LAR to radiate a laser beam to the window WIN.

Hereinafter, embodiments of a method of processing the window WIN using the laser defect removal apparatus LMA will be described in detail.

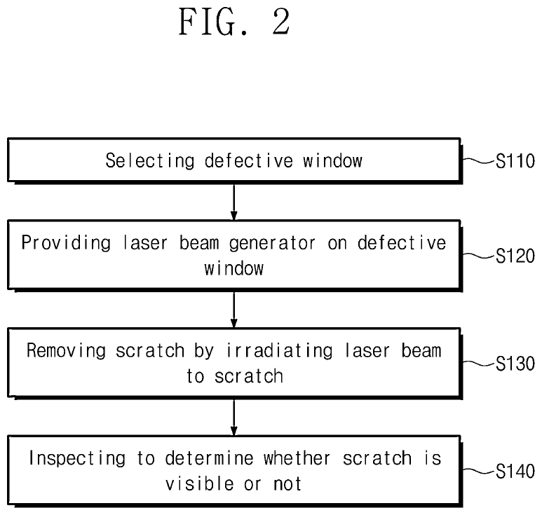

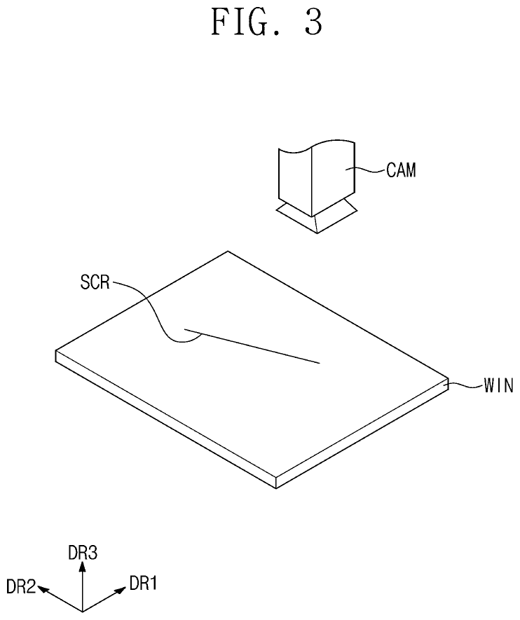

FIG. 2 illustrates a flow chart showing a window defect removal method according to an embodiment of the invention. FIGS. 3 to 8B illustrate diagrams sequentially showing a window defect removal method according to an embodiment of the invention.

Referring to FIGS. 2 and 3, in an embodiment of window defect removal method, defective windows WIN may be selected (S110).

In an embodiment, the window WIN may include at least one selected from glass, ceramic, ceramic glass and plastic. However, the material of the window WIN is not particularly limited.

The optical tool CAM disposed on the window WIN may capture an image of a surface of the window WIN.

The window WIN may include a scratch SCR that occurs during fabrication process or transfer procedure. In FIG. 3, for convenience of illustration and description, a single scratch SCR is illustrated, but a plurality of various-sized scratches SCR may occur during fabrication process and/or transfer procedure.

The optical tool CAM may capture the scratch SCR of the window WIN.

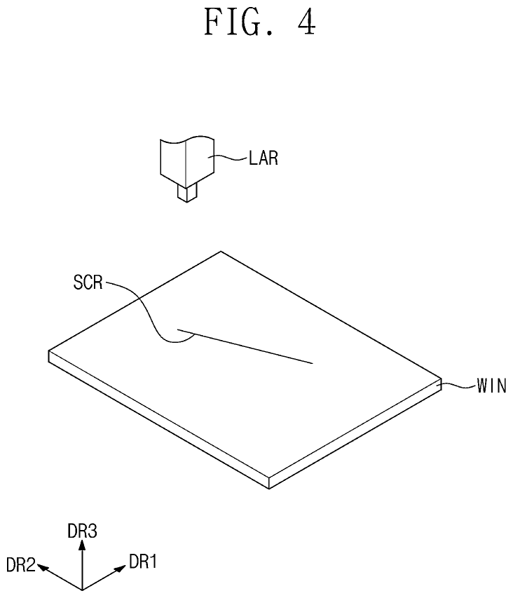

Referring to FIGS. 2 and 4, in such an embodiment, the laser beam generator LAR may be provided on the selected defective window WIN (S120).

The controller CC may control the laser beam generator LAR to move onto the scratch SCR of the window WIN.

Although not shown, the laser beam generator LAR may be connected to a transfer apparatus and may be transferred in a direction parallel to a plane of the window WIN, which is defined by a first direction DR1 and a second direction DR2. The laser beam generator LAR may be transferred along an extending direction of the scratch SCR on the window WIN.

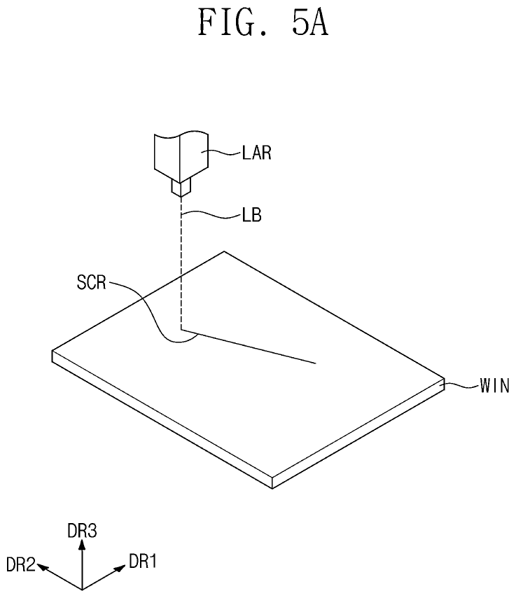

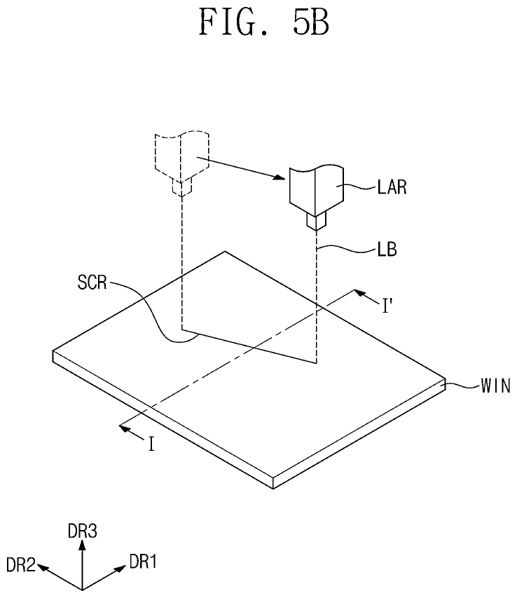

Referring to FIGS. 2, 5A, and 5B, in such an embodiment, a laser beam LB may be radiated to the scratch SCR, thereby removing the scratch SCR (S130).

The laser beam generator LAR may generate the laser beam LB. The laser beam LB may be radiated onto one lateral surface of the scratch SCR.

The laser beam LB may be a spot type laser beam, a surface type laser beam, or a line type laser beam.

The laser beam LB may be set to have a wavelength in a range of about 780 nanometers (nm) to about 100,000 nm. The scratch SCR of the window WIN may receive the laser beam LB in a wavelength range from about 780 nm to about 100,000 nm. In one embodiment, for example, the laser beam generator LAR may provide a CO₂ laser beam LB having a wavelength of about 10,600 nm, but the invention is not particularly limited thereto. In an embodiment where the scratch SCR of the window WIN is removed by the laser beam LB in a wavelength range from about 780 nm to about 100,000 nm, damage to the window WIN may be substantially reduced.

The laser beam generator LAR may radiate the laser beam LB onto an entirety of the scratch SCR, while moving from the one lateral surface toward another lateral surface of the scratch SCR,

An irradiation time of the laser beam LB to the scratch SCR may be equal to or less than about 1 minute. The invention, however, is not limited thereto, and the irradiation time of the laser beam LB may be variously changed depending on an area of the scratch SCR that occurs on the window WIN.

In comparison with a conventional processing method in which a polishing agent and a polishing brush are used to polish the window WIN, embodiments of the invention may reduce not only damage to the window WIN but also time spent to process the window WIN. In such embodiments of the invention, compared to the conventional polishing method, the surface of the window WIN may be effectively planarized.

The conventional processing method using polishing agent and brush may a difference in quality of the window WIN and induce an additional occurrence of defects due to changed properties of the polishing agent and the brush across lifespan thereof.

According to embodiments of the invention, the laser defect removal apparatus LMA may have an apparatus lifespan longer than that of the conventional polishing apparatus, such that difference in quality of the window WIN may be reduced and an additional occurrence of defects may be effectively prevented.

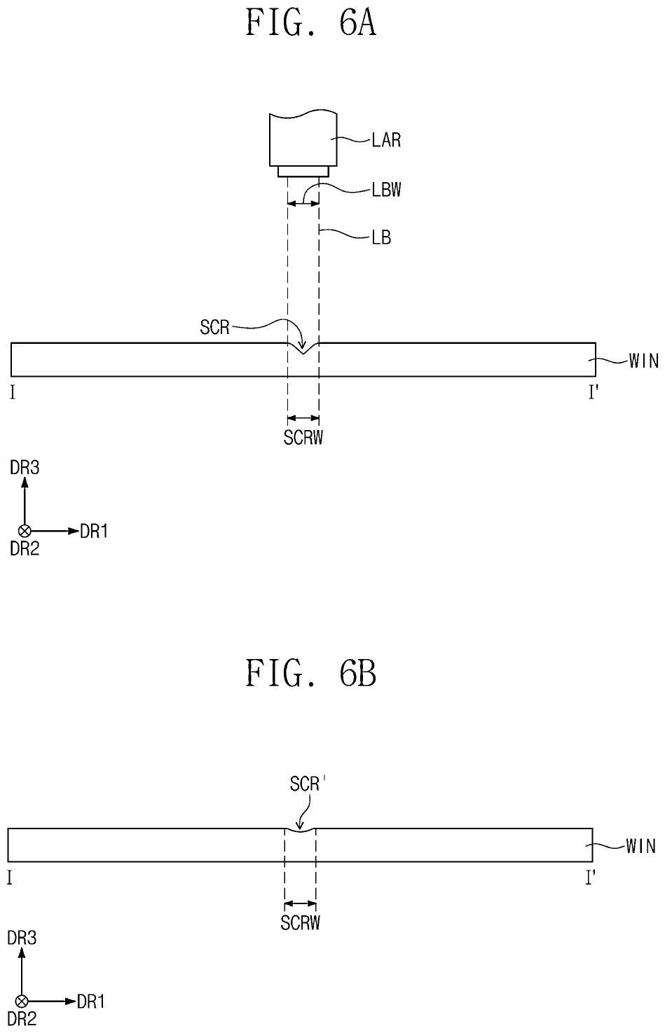

FIGS. 6A and 6B show schematic cross-sectional views taken along line I-I′ of the window WIN depicted in FIG. 5B. The scratch SCR occurring at the window WIN may be a portion that is recessed in a third direction DR3 from the surface of the window WIN. A width of the scratch SCR may be defined as a scratch width SCRW.

On both sides of the scratch width SCRW, the scratch SCR may be the least recessed. The scratch SCR may be recessed gradually deeper toward a central portion of the scratch width SCRW.

The laser beam LB may be set to have a certain width. The width of the laser beam LB may be defined as a laser beam width LBW. The laser beam width LBW may be determined based on the scratch width SCRW. The scratch width SCRW may be defined in a direction orthogonal to an extending direction of the scratch SCR or a traveling direction of the laser beam LB on a plane defined by the first direction DR1 and the second direction DR2. The laser beam width LBW may be set to be substantially the same as the scratch width SCRW.

The laser beam LB may be radiated to the scratch SCR and a location in the vicinity of the scratch SCR.

When the laser beam LB is radiated to the scratch SCR, the scratch SCR and surroundings thereof may be liquefied by heat.

The liquefaction of the scratch SCR and the surroundings thereof may proceed toward a central portion of the scratch SCR, and thus the scratch SCR may be planarized. The liquefied scratch SCR may then be solidified to form a processed scratch SCR′. The processed scratch SCR′ may have a flatter shape than that of the scratch SCR depicted in FIG. 6A.

The more the processed scratch SCR′ is flat, the less the scratch SCR′ is visible. When the scratch SCR′ is invisible, the window WIN may be utilized as a normal window.

Referring to FIGS. 2 and 7A to 8B, in an embodiment, an inspection may be performed to determine whether or not the scratch SCR is visible on the location to which the laser beam LB is radiated (S140).

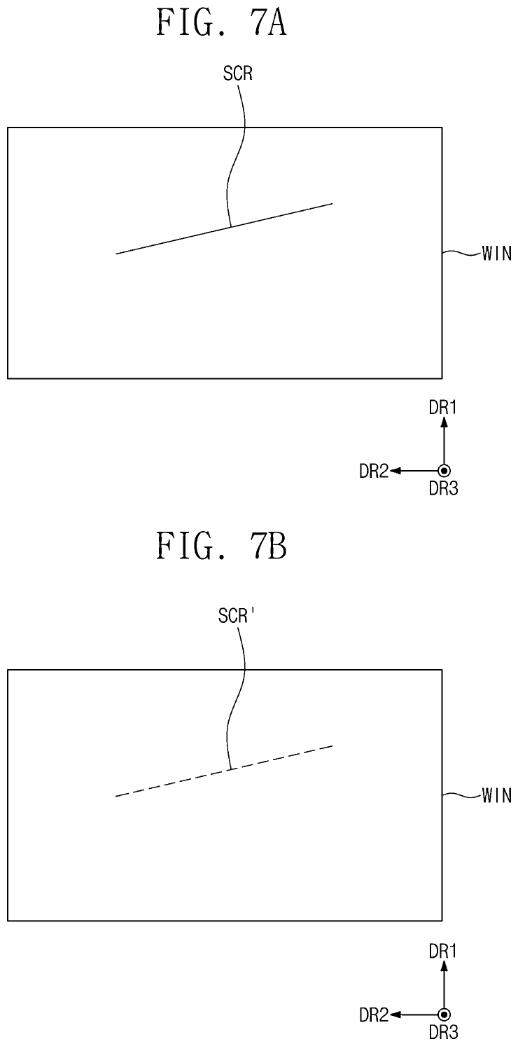

FIGS. 7A and 7B schematically show the scratch SCR before the irradiation of the laser beam LB and the processed scratch SCR′ after the irradiation of the laser beam LB in a case where the window WIN is observed by a microscope.

When using the microscope, it may be possible to observe the scratch SCR before the radiation of the laser beam LB. Because the processed scratch SCR′ after the irradiation of the laser beam LB is planarized by the laser beam LB, the processed scratch SCR′ may have a width smaller and shallower than that of scratch SCR before the radiation of the laser beam LB, and accordingly may be seen blurred on a monitoring screen.

Because the laser beam LB incurs less damages to the window WIN, the processed scratch SCR′ may be visible when observed by a microscope even after the radiation of the laser beam LB. In embodiments according to the invention, the radiation of the laser beam LB may be controlled to minimize damage to the window WIN.

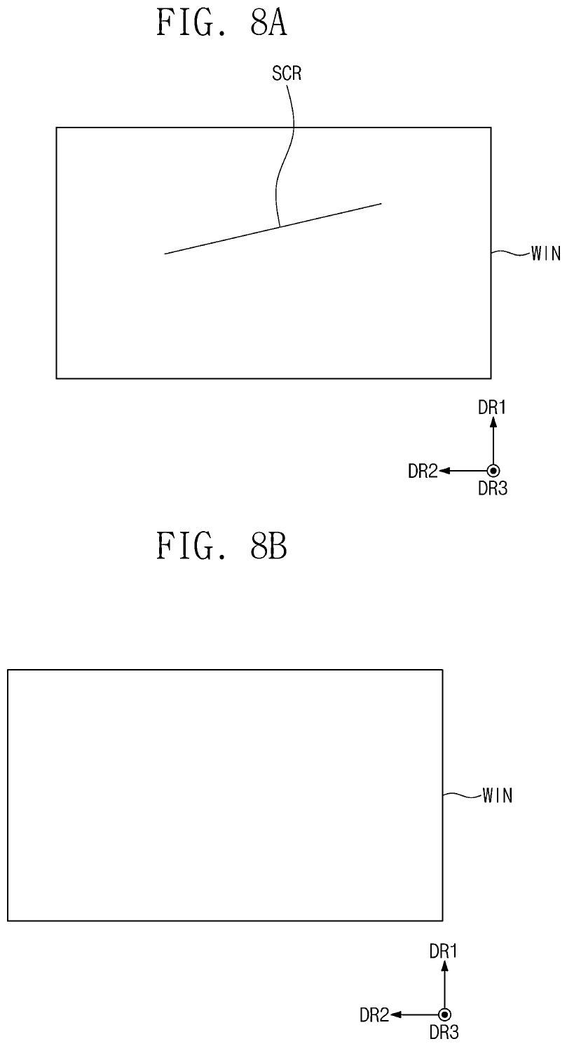

FIGS. 8A and 8B schematically show the scratch SCR before the radiation of the laser beam LB and the processed scratch SCR′ after the irradiation of the laser beam LB in a case where the window WIN is observed by a naked eye. The naked eye may be used to determine whether the scratch SCR′ is visible or not.

When using the naked eye, the scratch SCR before the radiation of the laser beam LB may be observed, but the processed scratch SCR′ after the radiation of the laser beam LB may not be observed. In embodiments according to the invention, the scratch SCR of the window WIN may be processed to be invisible only to the naked eye. Accordingly, damage to the window WIN may be minimized in a process for removing the scratch SCR of the window WIN.

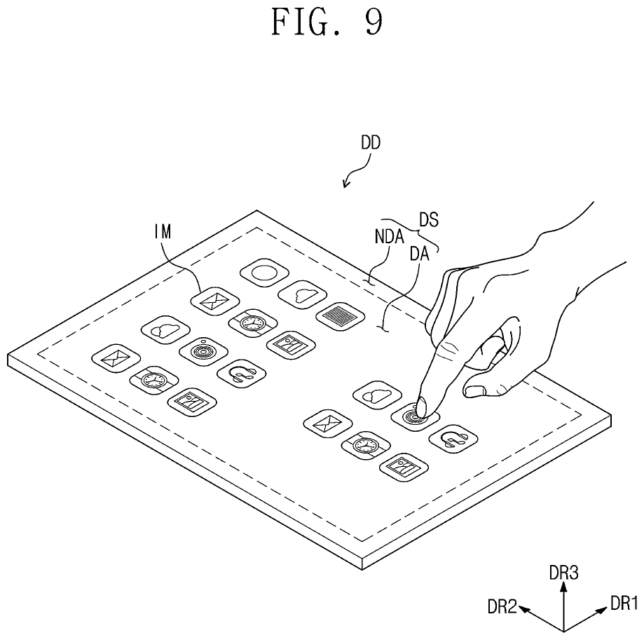

FIG. 9 illustrates a perspective view showing a display device fabricated by using a window according to an embodiment of the invention.

Referring to FIG. 9, an embodiment of a display device DD may include the window WIN according and have a rectangular shape with short sides that extend in a first direction DR1 and long sides that extend in a second direction DR2 intersecting the first direction DR1. The invention, however, is not limited thereto, and alternatively, the display device DD may have a circular shape, a polygonal shape, or any other suitable shape.

The display device DD may have a top surface defined as a display surface DS, and the top surface may have a plane defined by the first and second directions DR1 and DR2. The display surface DS may provide users with images IM generated from the display device DD.

The display surface DS may include a display region DA and a non-display region NDA around the display region DA. The display region DA may display an image, and the non-display region NDA may display no image. The non-display region NDA may surround the display region DA and may provide the display device DD with an edge that is printed with a certain color.

The display device DD may be used for large-sized electronic apparatuses such as televisions, monitors, or outdoor billboards, or may be used for small and medium-sized electronic apparatuses, such as personal computers, laptop computers, personal digital terminals, automotive navigation systems, game consoles, smart phones, tablet computers, or cameras, for example, but not being limited thereto. In embodiments, the display device DD may be used for any other electronic products without departing from the teachings herein.

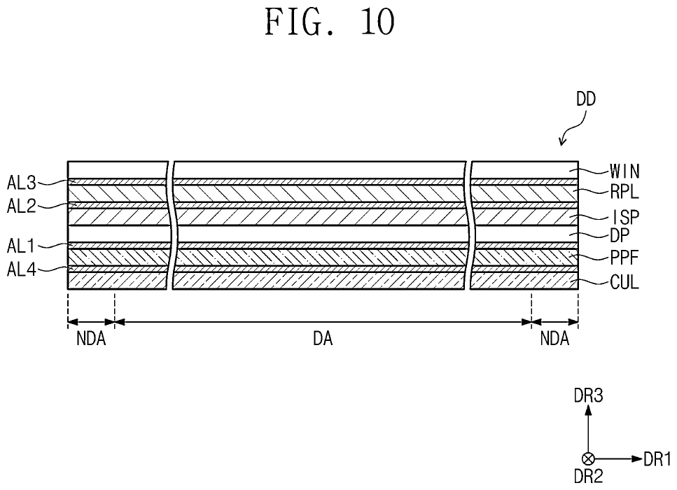

FIG. 10 illustrates a cross-sectional view showing an embodiment of the display device depicted in FIG. 9.

Referring to FIG. 10, an embodiment of the display device DD may include a display panel DP, an input sensing part ISP, an antireflection layer RPL, a window WIN, a panel protection film PPF, a cushion layer CUL, and first to fourth adhesion layers AL1 to AL4.

The input sensing part ISP, the antireflection layer RPL, and the window WIN may be disposed on the display panel DP. The panel protection film PPF and the cushion layer CUL may be disposed below the display panel DP.

The display panel DP may be a flexible display panel. In one embodiment, for example, the display panel DP may include a plurality of electronic elements disposed on a flexible substrate. In an embodiment, the display panel DP may include a display region DA and a non-display region NDA around the display region DA corresponding to those of the display device DD described above.

An embodiment of the display panel DP according to the invention may be an emissive display panel, but the invention is not particularly limited thereto. In one embodiment, For example, the display panel DP may be an organic light emitting display panel or a quantum-dot light emitting display panel. An emission layer of the organic light emitting display panel may include an organic light emitting material. An emission layer of the quantum-dot light emitting display panel may include a quantum-dot or a quantum-rod. Hereinafter, for convenience of description, embodiments where the display panel DP is an organic light emitting display panel will be described in detail.

In an embodiment, the input sensing part ISP may be disposed on the display panel DP. The input sensing part ISP may include a plurality of sensors (not shown) that detect an external input. The sensors may use a capacitive method to detect the external input. The input sensing part ISP may be directly fabricated on the display panel DP during a fabrication process. The invention, however, is not limited thereto, and alternatively, the input sensing part ISP may be fabricated in the form of an input sensing panel separately from the display panel DP and then attached through an adhesion layer to the display panel DP.

The antireflection layer RPL may be disposed on the input sensing part ISP. The antireflection layer RPL may be defined as a film for preventing reflection of external light. The antireflection layer RPL may reduce a reflectance of external light that is incident toward the display panel DP from outside the display device DD. In one embodiment, for example, the antireflection layer RPL may include at least one selected from a retarder and a polarizer.

The window WIN may be disposed on the antireflection layer RPL. The window WIN may protect the display panel DP, the input sensing part ISP, and the antireflection layer RPL against external scratches and impact. The window WIN may have optically transparent properties.

The panel protection film PPF may be disposed below the display panel DP. The panel protection film PPF may be defined as a protective substrate. The panel protection film PPF may protect a lower portion of the display panel DP. The panel protection film PPF may include a flexible plastic material. In one embodiment, for example, the panel protection film PPF may include polyethylene terephthalate (“PET”).

The cushion layer CUL may be disposed below the panel protection film PPF. The cushion layer CUL may absorb external impact applied to a lower portion of the display device DD, thereby protecting the display panel DP. The cushion layer CUL may include a resilient foam sheet.

The first adhesion layer AL1 may be disposed between the display panel DP and the panel protection film PPF. The first adhesion layer AL1 may combine the display panel DP and the panel protection film PPF with each other.

The second adhesion layer AL2 may be disposed between the antireflection layer RPL and the input sensing part ISP. The second adhesion layer AL2 may combine the antireflection layer RPL and the input sensing part ISP with each other.

The third adhesion layer AL3 may be disposed between the window WIN and the antireflection layer RPL. The third adhesion layer AL3 may combine the window WIN and the antireflection layer RPL with each other.

The fourth adhesion layer AL4 may be disposed between the panel protection film PPF and the cushion layer CUL. The fourth adhesion layer AL4 may combine the panel protection film PPF and the cushion layer CUL with each other.

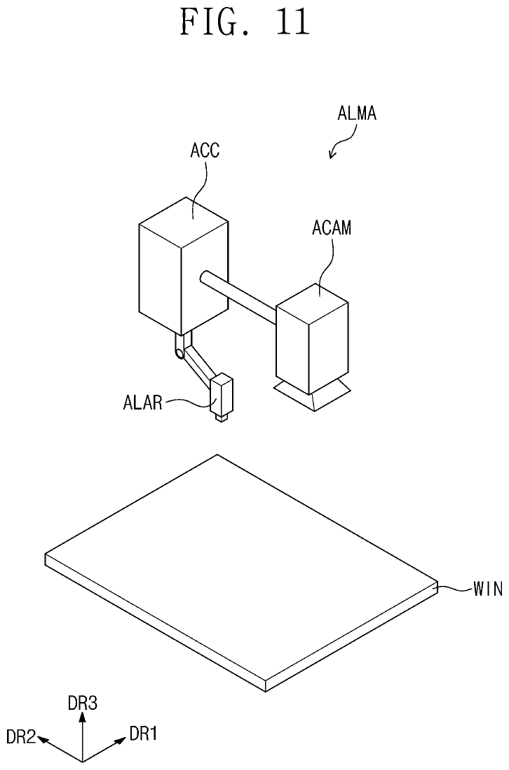

FIG. 11 illustrates a perspective view showing a laser defect removal apparatus according to an alternative embodiment of the invention.

Referring to FIG. 11, an embodiment of a laser defect removal apparatus ALMA may include an optical tool ACAM, a controller ACC, and a laser beam generator ALAR.

The laser defect removal apparatus ALMA may be automated to select a defective window WIN and to remove scratches of the defective window WIN.

The optical tool ACAM may capture an image of the window WIN and may transfer the captured image to the controller ACC.

The controller ACC may include a glass automatic inspection apparatus (not shown). The glass automatic inspection apparatus (not shown) may be configured such that the transferred image and a normal image are compared to inspect whether or not a scratch is on a surface of the window WIN. The controller ACC may select defective windows WIN on which the scratch exits.

The controller ACC may control a movement of the laser beam generator ALAR to provide the defective windows WIN with laser beams.

The controller ACC may control the laser beam generator ALAR to move onto the defective window WIN. The laser beam generator ALAR may radiate the laser beam to the scratch of the window WIN, thereby removing the scratch from the window WIN.

According to embodiments of the invention, scratches of a window may be removed while damage to the window is reduced and a surface of the window is effectively planarized.

In such embodiments, an apparatus lifespan is increased and a window processing time in decreased in comparison with a conventional method in which a polishing agent and a polishing brush are used, such that a difference in quality of the window may be reduced and an additional occurrence of defects may be effectively prevented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A window defect removal method, the method comprising:
inspecting a plurality of windows to select a defective window among the windows;
providing a laser beam generator on the defective window; and
irradiating a scratch of the defective window with a laser beam to remove the scratch,
wherein the laser beam generator generates the laser beam in a wavelength range from about 780 nm to about 100,000 nm.

2. The method of claim 1, wherein the inspecting the windows to select the defective window includes selecting a window on which the scratch exits as the defective window.

3. The method of claim 1, wherein the laser beam generator moves from one lateral surface of the scratch toward another lateral surface of the scratch along an extending direction of the scratch such that the laser beam is radiated to an entirety of the scratch.

4. The method of claim 3, wherein the irradiating the scratch of the defective window with the laser beam to remove the scratch includes allowing the laser beam to liquefy the scratch and surroundings thereof and then solidifying the liquefied scratch and the liquefied surroundings thereof.

5. The method of claim 1, wherein
a width of the laser beam is set to be a width of the scratch,
the width of the scratch is defined in a direction orthogonal to a traveling direction of the laser beam.

6. The method of claim 1, wherein the laser beam is a spot type laser beam, a surface type laser beam, or a line type laser beam.

7. The method of claim 1, wherein a radiation time of the laser beam is equal to or less than about 1 minute.

8. The method of claim 1, wherein the laser beam has a wavelength of about 10,600 nm.

9. The method of claim 1, wherein the window includes at least one selected from glass, ceramic and ceramic glass.

10. The method of claim 1, further comprising:
inspecting to determine whether or not the scratch is visible on a location to which the laser beam is radiated.

11. The method of claim 10, wherein whether or not the scratch is visible is determined by a naked eye.

12. The method of claim 1, wherein the inspecting the windows to select the defective window includes:
allowing an optical tool to capture images of the windows; and
allowing a controller to select a defective image among the images of the windows.

13. The method of claim 12, wherein the controller controls
a movement of the laser beam generator to provide the laser beam to the defective window corresponding to the defective image, and
an operation of selecting the defective window and an operation of removing the scratch of the defective window.

14. A laser defect removal apparatus, the apparatus comprising:
an optical tool on a window;
a laser beam generator which is transferred between the optical tool and the window, in a direction parallel to a plane of the window; and
a controller connected to the optical tool and the laser beam generator, wherein the controller controls an operation of each of the optical tool and the laser beam generator,
wherein the laser beam generator generates a laser beam in a wavelength range from about 780 nm to about 100,000 nm.

15. The apparatus of claim 14, wherein
the laser beam generated from the laser beam generator is radiated along an extending direction of the scratch from one lateral surface of a scratch of the window toward another lateral surface of the scratch, and
the scratch and surroundings thereof are liquefied by the laser beam and then are solidified.

16. The apparatus of claim 15, wherein
a width of the laser beam is set to be a width of the scratch,
the width of the scratch is defined in a direction orthogonal to a traveling direction of the laser beam, and
the laser beam is a spot type laser beam, a surface type laser beam, or a line type laser beam.

17. The apparatus of claim 16, wherein a radiation time of the laser beam is equal to or less than about 1 minute.
